(19) United States
(12) Patent Application Publication
(10) Pub. No.: US 2015/0241485 A1
(43) Pub. Date: Aug. 27, 2015

(54) APPARATUS AND METHOD FOR DETECTING THE ENERGY CONSUMPTION IN A LOCAL POWER SUPPLY SYSTEM

(71) Applicant: LOKISA Smart Energy GmbH, Mechernich (DE)

(72) Inventor: Christian SALEWSKI, Mechernich (DE)

(21) Appl. No.: 14/627,025

(22) Filed: Feb. 20, 2015

(30) Foreign Application Priority Data
Feb. 21, 2014 (DE) 10 2014 102 264.5

(51) Int. Cl. G01R 19/25; G01R 19/252

(52) U.S. Cl. CPC G01R 19/2513; G01R 19/2516; G01R 19/252

(57) ABSTRACT

An apparatus for detecting energy consumption in a local power supply system having at least one central line and a plurality of sublines branching from the central line and connected to consumers includes at least one detection unit for centrally detecting the individual energy consumptions of the individual consumers, the detection unit having an analog-to-digital converter detecting electric voltage on the central line. An analog input of the analog-to-digital converter is connected to the central line. The detection unit has a plurality of input channels, each input channel being coupled to a measuring transformer integrated into one of the sublines for measuring the flow of current through said subline. The detection unit is configured to successively sample the input channels and determine individual energy consumptions in each subline based on measured current flow through sublines and detected voltage on the central line.

### CROSS-REFERENCE TO PRIOR APPLICATIONS

Priority is claimed to German Patent Application No. DE 10 2014 102 264.5 filed on Feb. 21, 2014, the entire disclosure of which is hereby incorporated by reference herein.

### FIELD

This application is directed towards a method and apparatus for detecting the energy consumption in a local power supply system.

### BACKGROUND

t is a constant political, social and industrial aim to reduce greenhouse gas emissions by using the available energy in a more efficient manner in order to protect the environment. Furthermore, consistently rising energy prices ensure that saving energy is desirable not only for ecological but also economical reasons. Various public studies have shown that energy consumption can be reduced by 20 to 30 per cent merely by a change in consumer behaviour to more conscious and efficient use of electrical energy, without the user having to go without electrical devices and thus convenience for this purpose.

In order to be able to more efficiently use the electrical energy fed into a local power supply mains, for example a private household, a small business or a medium-sized industrial plant, the individual current consumptions of the individual consumers located in said local power supply mains must first be detected. Only once the individual consumers and the energy consumption or consumption profiles thereof have been identified can the local power supply mains together with the consumers be optimized and configured more efficiently, such as by exchanging individual consumers or modifying the respective switch-on times of individual consumers relative to one another, for example. A more conscious use of electrical energy by the consumer is also only possible if the consumer knows what the energy consumption of its main consumers is.

It is known from the prior art to centrally detect the energy consumption in a local power supply system by means of a current meter. Such a central detection of the current consumption is impractical for optimizing the local power supply mains along with the individual consumers thereof since only the total energy consumption is determined and no information regarding the individual energy consumption of the individual consumers in said power supply mains is obtained.

It is also known to detect the current consumption of individual technical devices using portable current consumption measuring devices which can be plugged in between the plug of the device and the socket. Such devices can monitor only individual devices and are therefore not suitable for central and professional determination of a dedicated energy footprint survey of all consumers incorporated in a local power supply system.

### SUMMARY

In an embodiment, the present invention provides an apparatus for detecting energy consumption in a local power supply system, the local power supply system having at least one central line and a plurality of sublines, the sublines branching from the central line and being connected to consumers. The apparatus includes: a detection unit configured to centrally detect individual energy consumptions of individual consumers, the detection unit including an analog-to-digital converter configured to detect an electric voltage on the central line, wherein at least one analog input of the analog-to-digital converter is connected to the central line, wherein the detection unit includes a plurality of input channels, wherein each input channel is coupled to a measuring transformer, the measuring transformer being integrated into one of the sublines, and the measuring transformer being configured to measure a current flow through the one of the sublines, wherein the detection unit is configured to successively sample the input channels and to determine the individual energy consumptions in each subline based on a measured current flow through respective sublines and the detected voltage on the central line.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 shows a schematic view of an apparatus and a method according to a first exemplary embodiment of the present invention;

FIG. 2 shows a schematic view of an apparatus and a method according to a second exemplary embodiment of the present invention; and

FIG. 3 shows a schematic view of an apparatus and a method according to a third exemplary embodiment of the present invention.

### DETAILED DESCRIPTION

An aspect of the invention provides an apparatus and a method for detecting the energy consumption in a local power supply system, which has at least one central line and a plurality of sublines, which branch from the central line and are connected to consumers, which apparatus and method enable the individual energy consumptions of the individual consumers to be determined by a centrally arranged detection unit. In addition, the apparatus and method are intended to be as simple, reliable, compact in terms of installation space and cost-effective as possible.

An aspect of the invention provides an apparatus for detecting the energy consumption in a local power supply system, which has at least one central line and a plurality of sublines, which branch from the central line and are connected to consumers, wherein the apparatus has at least one detection unit for centrally detecting the individual energy consumptions of the individual consumers, wherein the detection unit has at least one analog-to-digital converter for detecting the electric voltage on the central line, wherein an analog input of the analog-to-digital converter is connected to the central line, wherein the detection unit has a plurality of input channels, wherein each input channel is coupled to a measuring transformer which is integrated into one of the sublines for measuring the flow of current through said subline, wherein the detection unit is configured to successively sample the input channels and to determine the individual energy consumptions in each subline on the basis of the measured flow of current through said subline and the voltage, which has been subjected to analog-to-digital conversion, on the central line.

An apparatus according to the invention has the advantage that the energy consumptions occurring in the individual sublines owing to the consumers connected there are individually determined by a central detection unit. Thus, a consumption overview can be created showing how the total electrical energy consumed in the power supply system is divided between the individual consumers. As a result of the precise knowledge of said consumption overview, countermeasures can be taken, if appropriate, to save electrical energy or to more efficiently use the electrical energy or changes in consumer behavior can be brought about which lead to a more efficient use of electrical energy. By way of example, it would be conceivable for individual consumers the above-average energy consumption of which has been detected to be switched with shorter switch-on times or to be replaced by more energy-efficient devices. It would also be conceivable to operate such energy-intensive devices mainly at night when the electricity costs are lower. All such measures can be implemented in the form of a smart energy management scheme for saving energy and energy costs if a dedicated overview of the individual energy consumptions of the main consumers in the power supply system is available. The apparatus according to the invention is also not only suitable to compile said overview but also advantageously can be realized in a manner which is comparatively cost-effective and compact in terms of installation space. This is achieved by the electric voltage which should be the same in the entire power supply system being tapped centrally and supplied to the detection unit via the analog-to-digital converter which is integrated in the detection unit or is separate, while only the flow of current is measured in the respective sublines and is applied in the form of a measured current signal in each case to an input channel of the detection unit. The detection unit in this case has a multiplicity of input channels, with the result that an individual input channel is provided for each subline. The input channels are then sampled one after another by the detection unit at a particular frequency and read via the analog-to-digital converter or a further analog-to-digital converter, with the result that, advantageously, an individual analog-to-digital converter is not necessary for each measuring transformer or for each subline or consumer. In contrast, the successive sampling of the input channels enables the apparatus according to the invention to be realized with only a single analog-to-digital converter. Owing to the knowledge of the central electric voltage in the power supply system, the sampled current values can then be converted into electrical energy by the detection unit. Thus, the detection unit can precisely determine the individual energy consumption for each subline and, in particular, for each consumer assigned to a subline. The detection unit preferably comprises a microcontroller, a microprocessor and/or an FPGA (programmable logic circuit). It is conceivable that the analog-to-digital converter or the analog-to-digital converters is/are integrated in the microcontroller, microprocessor and/or FPGA or is/are realized completely or in part as separate components. It is also conceivable that parts of the detection unit, such as the input channels, for example, are implemented in an ASIC (application specific integrated circuit). The detection unit is preferably arranged in the region of a low-voltage sub-distribution board of a building, a service panel, a central distribution board or a feeder pillar. This is made possible by the fact that the apparatus is designed to be comparatively compact in terms of installation space. The detection unit optionally has a clock so that energy consumption temporal profiles can be created for the consumers.

Advantageous configurations and developments of the invention can be gathered from the dependent claims and the description with reference to the drawings.

According to a preferred embodiment of the present invention, provision is made for the apparatus to have a multiplexer, which, in the case of successive sampling of the input channels, switches the input channels one after the other to the analog input of the analog-to-digital converter or to an analog input of a further analog-to-digital converter. Thus, advantageously, a large number of sublines can be monitored using only one analog-to-digital converter. It is also conceivable for the outer conductors of the central conductors, usually one outer conductor or three outer conductors, likewise to be sampled on the analog-to-digital converter, with the result that the electric voltage on the central line is converted by the one analog-to-digital converter, too.

According to a preferred embodiment of the present invention, provision is made for the measuring transformers to comprise in each case a current transformer, in particular in the form of a push-through coil through which in each case the associated subline runs. The measuring transformer is connected via signal lines to a known measuring resistor across which a voltage which is proportional to the flow of current through the subline then falls. The resulting measured current signal is applied to the respective input channel and is converted into a digital value when sampled by the analog-to-digital converter. Multiplication of the measured current value by the central voltage then results in the electrical energy which is presently being consumed in the subline. It is conceivable that the respective measuring resistors are arranged in the region of the detection unit and, in particular, close to the input channels and not in the region of the sublines. Alternatively, it would also be conceivable to arrange the measuring resistors directly in the region of the measuring transformers.

According to a preferred embodiment of the present invention, provision is made for the measuring transformers to be directly permanently wired to the measuring resistors in each case via separate signal lines and/or indirectly permanently wired to the input channels. Thus, advantageously, a cost-effective and reliable coupling is possible between each measuring transformer and the respective associated input channel for transferring the measured current values. The signal transfer from the measuring transformers to the detection unit takes place over a wire link here. Alternatively, provision is made for the measuring transformers to be coupled in each case via a wireless radio link directly to the measuring resistors and/or indirectly to the input channels. The signal transfer from the measuring transformers to the detection unit therefore takes place wirelessly. Advantageously, an apparatus such as this can be comparatively easily, quickly and cost-effectively retrofitted into existing power supply systems since no additional lines need to be laid for transferring the measured current data.

An aspect of the invention provides for the measuring transformers to be permanently coupled to the detection unit only via the respective subline, wherein the measuring transformer has a modulator for modulating the measured data measured on the subline and wherein the apparatus has a demodulator, which is connected to the input channels of the detection unit, for demodulating the measured data modulated on the subline. Advantageously, neither a radio link nor the installation of additional lines for transferring the measured current data from the measuring transformers to the input channels of the detection unit are necessary here, since the measured current data is transferred via the sublines which exist anyway and lead to the central line.

According to another preferred embodiment of the present invention, provision is made for the detection unit to be configured such that the phase relation between voltage and current is determined for each subline on the basis of the time-dependent electric voltage detected on the central line and on the basis of the time-dependent electric current detected in the respective subline and, as a result of this, the real power arising in the subline in question is calculated. Advantageously, the phase relation of the electric voltage and the electric current can be taken into account, for example by determining the respective zero crossing, on the basis of the change in the electric voltage and the change in the electric current in the subline so that not only the apparent power but also the real power actually arising can be calculated in each subline. This is important, in particular, for private households which have consumers with a frequency-dependent phase shift and change in resistance since private households need to only the real power actually arising.

According to another preferred embodiment of the present invention, provision is made for the apparatus to have an evaluation unit connected to the detection unit for evaluating the individual energy consumptions of the individual consumers, wherein the evaluation unit preferably has a user interface, in particular a service console, and/or a machine interface, in particular a web interface. The evaluation unit also preferably has a clock and a memory for creating and storing temporal profiles of the energy consumptions. Advantageously, the energy consumptions and the temporal profiles of the energy consumptions can be directly displayed via the user interface and thus analysed by a user. For this purpose, the user interface comprises, for example, a display apparatus and input unit, such as a display and an input unit or a touchscreen or the like. Alternatively or in addition, the apparatus has a machine interface, with the result that the detected energy consumptions and temporal profiles can be automatically or manually read by an evaluation unit, for example in the form of a computer, a tablet PC or a smartphone. It is conceivable for the evaluation unit to be connected to the detection unit via a wire link, for example via a LAN cable, a USB cable or the like, or wirelessly, for example via WLAN, Bluetooth or IR. It is also conceivable for the evaluation unit to have a web interface, with the result that the detected energy consumptions and temporal profiles can be retrieved via the hypertext transfer protocol (HTTP).

According to another preferred embodiment of the present invention, provision is made for the evaluation unit to have a control unit which is provided for controlling consumers in the local power supply system. The control unit is used to automatically control the energy consumption in the local power supply system in order to optimize the energy consumption. It is conceivable for the control unit to be connected not only via the detection unit to energy consumers but also to energy sources, such as a photovoltaic installation, a wind turbine, an engine-generator or the like, for example, and/or to energy stores, such as lithium-ion rechargeable batteries, for example. The evaluation unit then detects not only the electrical energy consumed at the present instant or at a regularly recurring instant but also the stored electrical energy and the present electrical energy or the electrical energy regularly generated at particular instants. In order to efficiently use the energy, the consumers are now preferably controlled—provided the switch-on times thereof are variable —such that the electrical energy generated by the energy sources can be consumed directly within the local power supply system or can be used to charge the energy stores. Furthermore, the switching-on of energy-intensive consumers is avoided when no electrical energy is presently being generated by the energy sources and the energy stores are completely discharged.

A further aspect of the present invention is a method for detecting the energy consumption in a local power supply system, which has at least one central line and a plurality of sublines, which branch from the central line and are connected to consumers, in particular for detecting by means of an apparatus according to any of the preceding claims, having the steps of:
detecting the electric voltage on the central line;
converting the detected voltage value into a digital voltage value by means of at least one analog-to-digital converter;
detecting flows of current flowing through sublines to the consumers by means of measuring transformers integrated in each case in the sublines,
transferring the detected measured current value to separate input channels of a detection unit;
successive sampling of the input channels of the detection unit;
determining the individual energy consumptions in each subline on the basis of the sampled measured current value for said subline and the voltage, which was subjected to analog-to-digital conversion, on the central line.

A method according to the invention enables the energy consumptions occurring in the sublines owing to the consumers connected there to be individually determined by a central detection unit, without a comparatively large and cost-intensive analog-to-digital converter being required for each subline. In this case, temporal profiles of the energy consumptions of the individual consumers are preferably created by means of an evaluation unit. The precise knowledge of the energy consumptions and temporal profiles then enable a smart energy management scheme for exploiting all of the energy-saving potential. It is conceivable for the measured current values present at the input channels, and optionally the voltage value of at least one outer conductor of the central line (alternatively: three outer conductors in the case of three-phase current), to be successively switched to an analog input of the analog-to-digital converter by means of a multiplexer.

According to another preferred embodiment of the present invention, provision is made for the measured current values to be detected by means of measuring transformers in the form of current transformers and, in particular, push-through coils and to be converted into measured current values by means of measuring resistors. Advantageously, a voltage (also referred to as measured current value) which is proportional to the current is induced in the coil and drops across the measuring resistor (also referred to as “shunt”), as a result of which a voltage proportional to the current in the subline can be tapped at the known measuring resistor.

According to another preferred embodiment of the present invention, provision is made for the measured current values measured by the measuring transformers to be transferred in each case via separate signal lines or via a wireless radio link indirectly via the measuring resistor to the input channels. Alternatively, it is conceivable that the measured current values measured by the measuring transformers are modulated on the subline and are demodulated again at the detection unit by a demodulator and applied to the input channels. In this way, advantageously, no new lines need to be installed for the method according to the invention to be realized.

According to another preferred embodiment of the present invention, provision is made for the individual consumers in the local power supply system to be controlled by means of a control unit on the basis of the detected energy consumptions and, in particular, the consumption profiles. As has already been mentioned, the control unit is used to automatically control the energy consumption in the local power supply system in order to optimize the energy consumption. It is conceivable for the control unit not only to obtain present energy consumption data from the consumers but also from energy sources and/or energy stores in order to appropriately control the consumers.

Further details, features and advantages of the invention emerge from the drawings and from the following description of preferred embodiments with reference to the drawings. The drawings illustrate merely exemplary embodiments of the invention which do not restrict the essential scope of the invention.

In the various figures, identical parts are always provided with identical reference signs and are therefore generally also mentioned only once in each case.

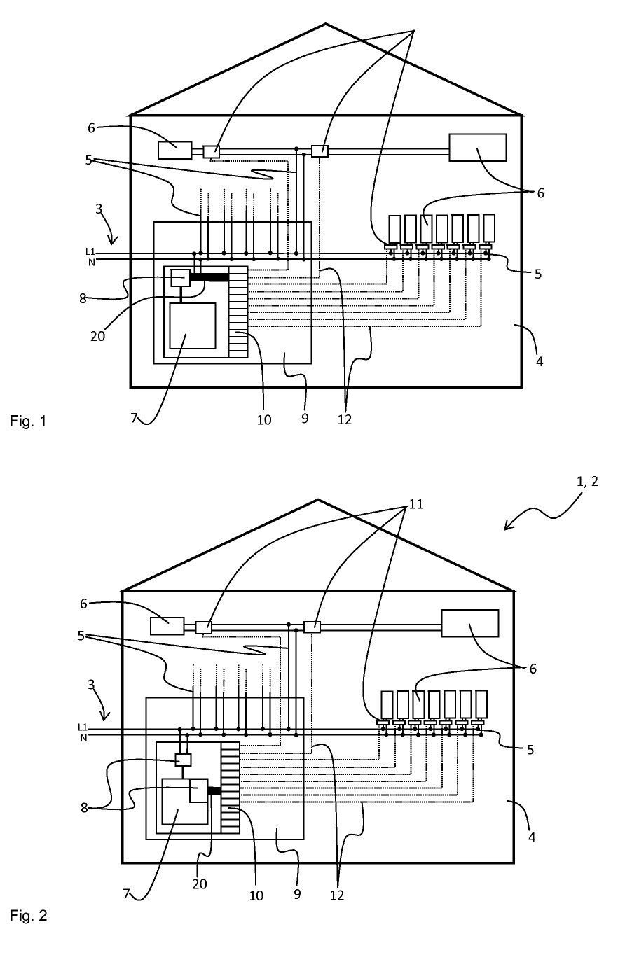

FIG. 1 illustrates a schematic view of an apparatus 1 and a method according to a first exemplary embodiment of the present invention. The apparatus 1 is used to detect the energy consumption in a local power supply system 2. In the present example, the power supply system 2 comprises the power supply mains of a private household 4. The power supply mains has a central line 3 which is connected to a house transfer point. A plurality of sublines 5 branch from said central line 3 in a central distribution board 9, which sublines lead, for example, to individual rooms, to individual floors, to individual consumers 6 or to individual sockets or the like.

The apparatus 1 has a detection unit 7 which is connected to at least one analog-to-digital converter 8 and has a plurality of input channels 10. The detection unit 7 preferably has a microprocessor, a microcontroller or the like. The analog-to-digital converter 8 is connected on the input side to the central line 3 via a multiplexer 20 and on the output side to the detection unit 7 and is used to measure the electric voltage on the central line 3 and to transfer it as digital voltage value to the detection unit 7. The digital voltage value detected in this way by the detection unit 7 applies to the whole power supply mains since the electric voltage is substantially constant in the entire power supply system 2.

The input channels 10 are in each case coupled to measuring transformers 11. Precisely one measuring transformer 11 is integrated into each monitored subline 5, which measuring transformer is used to measure the electric current through the associated subline 5. For this purpose, each measuring transformer 11 has a current transformer in the form of a push-through coil, through which the subline runs. The windings of the push-through coil are connected in each case to a measuring resistor (shunt) arranged in the region of the input channels 10 via signal lines 12. The voltage drop across the measuring resistor is in this case applied as measured current value to the associated input channel 10. The various input channels 10 are likewise connected via the multiplexer 20 to the analog-to-digital converter 8 and are sampled one after the other by the detection unit 7 in order to tap the associated measured current value for each monitored subline. Since the electrical resistance of the measuring resistor is known, it is possible for the sampled measured current value to be converted into a current value which is proportional to the flow of current through the associated subline 5 within the detection unit 7. Then, for each subline 5, the calculated current value is multiplied by the voltage, which has been centrally detected on the central line 3 and subjected to analog-to-digital conversion, in the detection unit 7. In this way, it is possible for the present energy consumption of each consumer 6 attached to one of the sublines 5 to be determined at a central point of the power supply system 2 by means of the detection unit 7. Preferably, the input channels 10 and the central line 3 are sampled at a predefined frequency, with the result that not only is the present instantaneous consumption of any consumer 6 calculated but also the temporal profile of current and voltage in each subline is determined. In each case the zero crossing of current and voltage can be determined from the temporal profiles, as a result of which the real power can also be calculated for each consumer 6. It is also conceivable for the apparatus 1 to have a clock and thus for it to be possible to generate a precise temporal profile of the respective energy consumption for each consumer 6. Advantageously, the apparatus 1 does not require a dedicated analog-to-digital converter for each subline 5, with the result that the apparatus 1 can be realized in a manner which is comparatively compact in terms of installation space and energy-saving. As a result of this, in particular, installation of the detection unit 7 in the central distribution board 9 is conceivable.

The measured current data can be transferred from the individual measuring transformers 11 to the measuring resistors and input channels 10 via the separate signal lines 12 or wirelessly. However, it would also be conceivable for the measured voltage data to be modulated on the respective subline 5 by means of a modulator. The apparatus 1 then has demodulators in the region of the input channels 10, which demodulators demodulate the measured voltage data which was modulated on the sublines 5 again and apply said data to the input channels 10. In the case of this solution, advantageously no separate signal lines 12 are required.

The detection unit 7 preferably has a user interface, preferably in the form of a touchscreen, via which a user can analyse, process, export, store, compare etc. the created energy consumptions and temporal profiles. Alternatively or in addition, the detection unit has a machine interface via which the data can be mechanically retrieved. It is conceivable that the created energy consumptions and temporal profiles can be retrieved, for example, by means of a web interface via hypertext transfer protocol (HTTP). As a result of the precise knowledge of the energy consumptions and temporal profiles in the local power supply system 2, countermeasures for saving electrical energy or for more efficient usage of the electrical energy can be taken, if appropriate, by the user. By way of example, it would be conceivable for individual consumers 6 the above-average energy consumption of which has been detected to be switched with shorter switch-on times or to be replaced by more energy-efficient devices. It would also be conceivable to operate such energy-intensive devices mainly at night when the electricity costs are lower.

FIG. 2 illustrates a schematic view of an apparatus 1 and a method according to a second exemplary embodiment of the present invention. The second embodiment is substantially identical to the first embodiment illustrated in FIG. 1, wherein, in contrast to the first embodiment, two analog-to-digital converters 8 are realized in the case of the second embodiment: an analog-to-digital converter 8 which is separate from the detection unit 7 and which samples only the electric voltage across the central line 3 and a further separate analog-to-digital converter 8 on which the input channels 10 are sampled by means of the multiplexer 20. Optionally, the functionality of the two separate analog-to-digital converters 8 can also be realized by a single integrated or separate analog-to-digital converter 8.

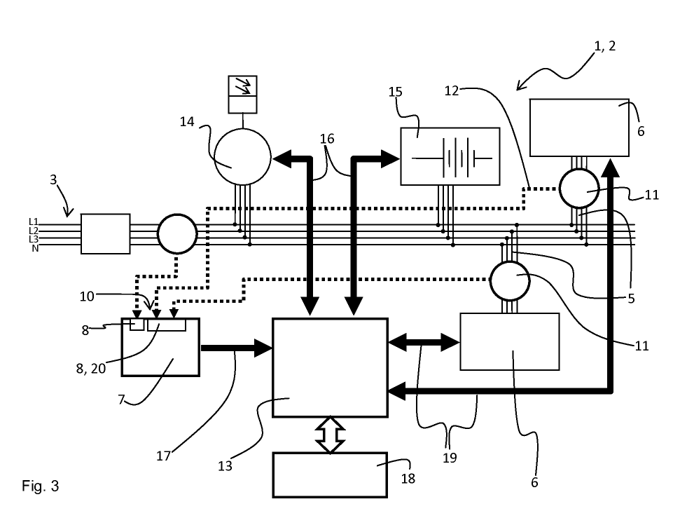

FIG. 3 illustrates a schematic view of an apparatus 1 and a method according to a third exemplary embodiment of the present invention. The third embodiment is substantially identical to the first embodiment illustrated in FIG. 1, wherein the apparatus 1 according to the third embodiment additionally has an evaluation and control unit 13 for evaluating the data calculated by the detection unit 7 and for controlling the consumers 6 on the basis of the evaluation results. In addition, the local power supply system 2 in the case of the third embodiment is illustrated by way of example as a three-phase AC system, in contrast to the first embodiment. The three electric voltages on the three outer conductors (L1, L2, L3) of the central line 3 are therefore firstly individually tapped at a measuring point 14 and then sampled in each case successively by an analog-to-digital converter 8 and transferred to the detection unit 7. Furthermore, the measuring transformers 11 have in each case three push-through coils, wherein each outer conductor L1, L2, L3 runs through one push-through coil. Each push-through coil is connected via signal lines 12 to a measuring resistor arranged in the detection unit 7, wherein the measured current value dropping across the respective measuring resistor is applied to an input channel 10. By means of a multiplexer 20, the measured current values are sampled one after another by an analog-to-digital converter 8 integrated in the detection unit 7. The electrical energy consumption for the respective subline 5 is calculated after the measured current values are sampled, taking into account the present electric voltage.

In contrast to the first embodiment, the power supply system 2 according to the third embodiment also has not only consumers 6 but also an energy source 14 in the form of a photovoltaic installation and an energy store 15 in the form of a battery. The present feed-in and state of charge data of the energy source or of the energy store are transferred via separate data lines 16 to the evaluation and control unit 13. Furthermore, the evaluation and control unit 13 obtains the energy consumption data detected by the detection unit 7 together with associated temporal profiles of the consumers 6 via a further separate data line 17. Furthermore, the evaluation and control unit 13 is connected via control lines 19 to the consumers 6, with the result that active control of the switch-on times of the consumers 6 is made possible by the evaluation and control unit 13.

Now, all of the information relating to the present and the expected energy consumption of the consumers 6, and the available capacities of local energy sources 14 and stores 15, is present in the evaluation and control unit 13. On the basis of said information, an efficient energy management scheme is created by the evaluation and control unit 13 and the consumers 6 are controlled on the basis of said energy management scheme. By way of example, it is conceivable for a consumer in the form of a cooling unit for a refrigerated room to be operated at relatively high power throughout the day since additional energy is available from the photovoltaic installation during the day and the door to the refrigerated room must often be opened, and it is conceivable for the cooling unit to be operated at low power overnight since the door generally remain closed overnight and additional energy is only available from the energy store. A smart control option such as this for a consumer 6 is automatically recognized and realized by the evaluation and control unit 13 on the basis of the associated temporal profile.

The evaluation and control unit 13 also preferably has a web interface 18, which permits remote maintenance or remote control of the evaluation and control unit 13.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B, and C” should be interpreted as one or more of a group of elements consisting of A, B, and C, and should not be interpreted as requiring at least one of each of the listed elements A, B, and C, regardless of whether A, B, and C are related as categories or otherwise. Moreover, the recitation of “A, B, and/or C” or “at least one of A, B, or C” should be interpreted as including any singular entity from the listed elements, e.g., A, any subset from the listed elements, e.g., A and B, or the entire list of elements A, B, and C.

### LIST OF REFERENCE SIGNS

1 Apparatus
2 Power supply system
3 Central line
4 Private household
5 Subline
6 Consumer
7 Detection unit
8 Analog-to-digital converter
9 Distribution board
10 Input channel
11 Measuring transformer
12 Signal lines
13 Evaluation and control unit
14 Energy source
15 Energy store
16 Data line
17 Data line
18 Web interface
19 Control line
20 Multiplexer

1. An apparatus for detecting energy consumption in a local power supply system, the local power supply system having at least one central line and a plurality of sublines, the sublines branching from the central line and being connected to consumers, the apparatus comprising:
a detection unit configured to centrally detect individual energy consumptions of individual consumers, the detection unit including an analog-to-digital converter configured to detect an electric voltage on the central line,
wherein at least one analog input of the analog-to-digital converter is connected to the central line,
wherein the detection unit includes a plurality of input channels,
wherein each input channel is coupled to a measuring transformer, the measuring transformer being integrated into one of the sublines, and the measuring transformer being configured to measure a current flow through the one of the sublines,
wherein the detection unit is configured to successively sample the input channels and to determine the individual energy consumptions in each subline based on a measured current flow through respective sublines and the detected voltage on the central line.

2. The apparatus of claim 1, further comprising:
a multiplexer, which, in a case of successive sampling of the input channels, switches the input channels one after another
to the analog input of the analog-to-digital converter, or
to a further analog input of a further analog-to-digital converter.

3. The apparatus of claim 1, wherein each measuring transformer includes a current transformer.

4. The apparatus of claim 1, wherein each measuring transformer includes a current transformer in the form of a push-through coil through which an associated subline runs.

5. The apparatus of claim 2, further comprising:
a measuring resistor for each measuring transformer,
wherein, in each case, one measuring resistor is coupled to an input channel.

6. The apparatus of claim 1, wherein each measuring transformer is permanently wired to an associated measuring resistor via one or more separate signal lines, and
wherein each measuring transformer is indirectly permanently coupled to an associated input channel.

7. The apparatus of claim 1, wherein each measuring transformer is at least indirectly coupled to an associated input channel via one wireless radio link.

8. The apparatus of claim 1, further comprising:
a modulator configured to modulate measured data from the subline; and
a demodulator configured to demodulate modulated data from the subline,
wherein the measuring transformers are indirectly coupled to the input channels via a respective subline.

9. The apparatus of claim 1, wherein the central line includes a first, second, and third outer conductor,
wherein the first, second, and third outer conductors can be switched one after another to the analog input of the analog-to-digital converter.

10. The apparatus of claim 1, wherein the detection unit is configured such that a phase relation between voltage and current is determined for each subline based on a time-dependent electric voltage detected on the central line and based on a time-dependent electric current detected in a respective subline and, as a result of this, real power arising in an analyzed subline is calculated.

11. The apparatus of claim 1, wherein the detection unit includes at least one of a microcontroller, a microprocessor, or a programmable logic circuit (FPGA).

12. The apparatus of claim 1, wherein the detection unit is arranged in a region of a low-voltage sub-distribution board of a building, a service panel, a central distribution board, or a feeder pillar.

13. The apparatus of claim 1, further comprising an evaluation unit connected to the detection unit, the evaluation unit being configured to evaluating the individual energy consumptions of the individual consumers.

14. The apparatus of claim 1, further comprising:
a clock; and
a memory,
configured to create and save one or more temporal profiles of the energy consumptions.

15. A method for detecting energy consumption in a local power supply system, the local power supply system having at least one central line and a plurality of sublines, the sublines branching from the central line and being connected to consumers, the method comprising:
detecting an electric voltage on the central line, to obtain a detected voltage value;
converting the detected voltage value into a digital voltage value using at least one analog-to-digital converter;
detecting one or more current flows flowing through sublines to the consumers using one or more measuring transformers integrated in each case in the sublines,
transferring the detected measured current value to separate input channels of a detection unit;
successively sampling the input channels of the detection unit;
determining individual energy consumptions in each subline based on a sampled measured current value for an associated subline and the converted voltage value.

16. The method of claim 15, comprising:
creating temporal profiles of the energy consumptions of the individual consumers using an evaluation unit.

17. The method of claim 15, comprising:
successively switching measured current values present at the input channels to an analog input of the analog-to-digital converter using a multiplexer.

18. The method of claim 15, comprising:
detecting current flowing through respective sublines using one or more current transformers, to obtain detected current values; and
converting the detected current values into measured current values using one or more measuring resistors.

19. The method of claim 15, comprising:
transferring at least one of the currents measured by the measuring transformers, and the measured current values to the input channels in each case via a separate signal line or via a wireless radio link.

20. The method of claim 15, comprising:
modulating the measured current values measured using the one or more measuring transformers on the subline, to obtain modulated values; and
demodulating the modulated values using the apparatus, to obtain processed values; and
applying the processed values to the input channels.
